(19) United States
(12) Patent Application Publication
(10) Pub. No.: US 2006/0160360 A1
(43) Pub. Date: Jul. 20, 2006

(54) Evaporation method and evaporator

(76) Inventors: Masayuki Toda, Yamagata (JP); Masaki Kusuhara, Tokyo (JP)

Correspondence Address: YOUNG & THOMPSON, 745 SOUTH 23RD STREET, 2ND FLOOR, ARLINGTON, VA, 22202, US

(21) Appl. No.: 10/561,512

(22) PCT Filed: Jun. 21, 2004
(86) PCT No.: PCT/JP04/08718

§ 371 Date: Mar. 8, 2006

(30) Foreign Application Priority Data
Jun. 20, 2003 (JP) 2003-177378

(51) Int. Cl. H01L 21/44

(52) U.S. Cl. 438/681

(57) ABSTRACT

A vaporization method and a vaporizer capable of greatly reducing the number of fine particles scattered in a film after film formation. A raw material solution is brought into contact with a heated carrier gas and carried to a subsequent step. The vaporizer includes: a vaporization chamber; a carrier gas passage communicating with the vaporization chamber; a raw material solution lead-in port through which the raw material solution is led into the passage; and elements for heating the carrier gas.

### TECHNICAL FIELD

The present invention relates to a vaporization method and a vaporizer which can perform atomization and vaporizing decomposition of a liquid raw material without reducing a temperature of an air current in a high-temperature region or a flow path maintained at a high temperature of, e.g., an MOCVD apparatus.

### BACKGROUND ART

Patent Reference 1: Japanese Patent Application Laid-open No. 2000-216150. As one of devices crucial for semiconductor device manufacture, there is a CVD apparatus. Most of reaction chemical species supplied to this CVD apparatus are gases. However, a raw material obtained by solving an organic metal complex in an organic solvent must be used depending on a type of a thin film to be manufactured. This example is production of a ferroelectric thin film or the like by an MOCVD apparatus. In this case, a raw material must be transported and atomized by appropriate devices in order to prepare raw material vapor. Under the present situation, however, there are few devices which can maintain a concentration of a vaporized raw material constant and continuously and stably operate without clogging a vaporizer.

As a technology which has solved the above-described problem, there is known one disclosed in (Patent Reference 1). FIG. 1 shows this apparatus.

This apparatus is a technology which allows an atomized raw material solution to be contained in a carrier gas and then performs vaporization. Further, in this technology, the carrier gas is not heated by cooling a supply passage and a gas passage for the raw material solution.

However, when vaporization and film formation were carried out by using this technology, it was found that fine particles of approximately 1 μm are scattered in a formed film.

### DISCLOSURE OF THE INVENTION

Problem to be Solved by the Invention

It is an object of the present invention to provide a vaporization method and a vaporizer capable of greatly reducing the number of fine particles scattered in a film after film formation.

Means for Solving the Problem

A vaporizer according to the present invention is a vaporization method characterized in that a raw material solution is brought into contact with a heated carrier gas and carried to a subsequent step.

Moreover, a vaporizer according to the present invention is a vaporizer characterized by having: a vaporization chamber; a carrier gas passage communicating with the vaporization chamber; a raw material solution lead-in port through which a raw material solution is led into the passage; and means for heating the carrier gas.

Effects of the Invention

The present inventors eagerly explored a factor of scattering of fine particles in a film in the prior art.

As a result, they assumed that a raw material solution which is sheared by a carrier gas and contained in the form of mist or steam having a particle diameter of 1 μm or below in the carrier gas is not gasified even in a vaporization chamber for some reason, and fine particles are not vaporized, but introduced into a film formation chamber as they are and then solidified.

Based on such an assumption, when they conducted various kinds of experiments while changing many conditions existing in vaporization and film formation in many ways, they discovered that using a heated carrier gas as the carrier gas can greatly reduce the number of the fine particles.

That is, in the present invention, the heated carrier gas is used as the carrier gas, and the fine particles in a film can be thereby greatly reduced.

Although its detailed reason is not clear, it can be considered that, when a raw material solution is introduced into the heated carrier gas, the raw material solution is atomized and instantaneously gasified.

As means for introducing the raw material into the carrier gas for atomization, arbitrary means can be used.

Means for heating the carrier gas is not restricted. It is good enough for the carrier gas to be heated at least before being brought into contact with the raw material solution.

### BRIEF DESCRIPTION OF THE DRAWINGS

FIG. 1 is a cross-sectional view showing a primary part of an MOCVD vaporizer used in an embodiment.

### DESCRIPTION OF REFERENCE NUMERALS

1 dispersing portion main body

2 gas passage

3 carrier gas

4 gas lead-in port

5 raw material solution

6 raw material supply hole

7 gas outlet

8 dispersing portion

9a, 9b, 9c and 9d screw

10 rod

18 means for cooling (a cooling water)

20 vaporizing tube

21 heating means (a heater)

22 vaporizing portion

23 connecting portion

### BEST MODE FOR CARRYING OUT THE INVENTION

It is characterized that a temperature of the heated carrier gas is 100 to 300° C.

It is characterized that a temperature of the heated carrier gas is 200 to 250° C.

Although a reduction in fine particles is recognized at 50° C. or above as a temperature of the carrier gas, a further reduction tendency appears by setting this temperature to 100° C. or above. 200° C. or above is more preferable.

It is characterized that the raw material solution is obtained by solving an organic metal compound in a solvent. Fine particles are apt to be scattered when the raw material is an organic metal in particular in the prior art, but the present invention can greatly reduce scattering of fine particles even when the raw material is an organic metal.

It is characterized that the carrier gas is an inert gas.

It is characterized that the carrier gas is a gas containing an oxidizing gas in an inert gas. When an oxidizing gas is contained in the carrier gas, a content of carbon a formed film is considerably reduced, and the number of fine particles is also decreased.

It is characterized that a speed of the carrier gas is set to a subsonic speed to a sonic speed to introduce the raw material solution. The carrier gas is allowed to flow at a sonic speed or below, and the raw material solution introduced into the carrier gas may be condensed in some cases when a speed of the carrier gas exceeds the sonic speed. However, setting a speed of the carrier gas to the subsonic speed or above is preferable. By setting a speed of the carrier gas to the subsonic speed or above, a shearing effect with respect to the raw material solution can further excellently function, and the raw material solution has a particle diameter of 1 μm or below and is atomized in the carrier gas.

It is characterized that the raw material solution is introduced into a passage of the carrier gas through a hole having a diameter of 0.05 mm to 0.5 mm. It is preferable to introduce the raw material solution through the hole having a diameter of 0.05 mm to 0.5 mm in view of atomization of 1 μm or below. Adopting such a diameter and setting a speed of the carrier gas to the sonic speed or below can readily generate mist of 1 μm or below.

It is characterized that a solvent for the raw material solution is contained in the carrier gas before introducing the raw material solution. Containing the solvent can effectively prevent the raw material solution from being condensed.

It is characterized that a raw material concentration in the raw material solution is not greater than 0.2 mol/L. Using the raw material solution whose raw material concentration is not greater than 0.2 mol/L can achieve uniform atomization.

It is to be noted that an arbitrary material is used as the raw material, but the present invention is more effective with respect to, e.g., SBT, PZT, BST, LBT and others which are MOCVD raw materials. In case of such raw materials, the raw material and the solvent are subjected to vaporizing decomposition while simultaneously performing atomization, thereby greatly reducing occurrence of fine particles.

Incidentally, even in the present invention, it is preferable for a member around a flow path through which the raw material, the solvent and a neutral or oxidizing gas having a high temperature flow to be formed of a material having high heat shielding properties as described in Patent Reference 1. That is because liquid temperatures of the raw material and the solvent can be maintained at lower temperatures until a moment of atomizing the MOCVD raw material and the solvent by using a high-temperature and high-speed air current, and evaporation of the solvent and degeneration of the raw material can be avoided in this way.

### Embodiment 1

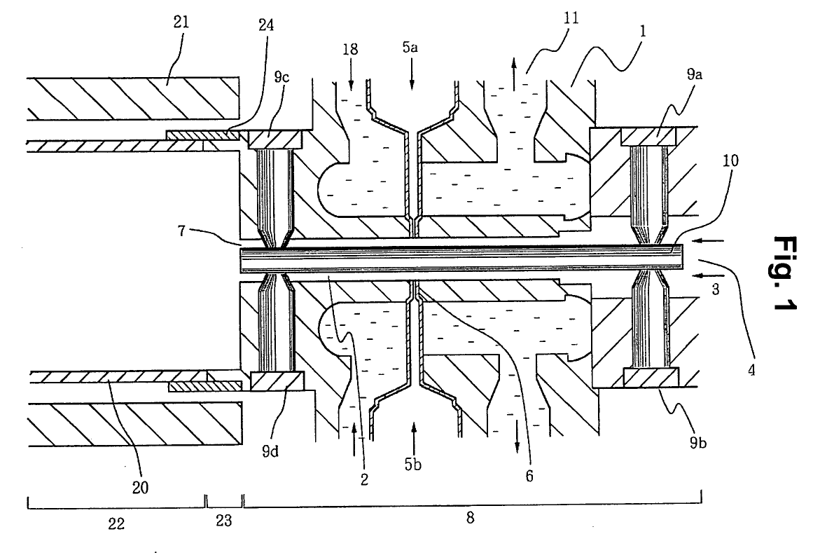

In this example, formation of an SBT film was carried out. An apparatus used is an apparatus shown in FIG. 1.

A raw material concentration of an organic metal complex abbreviated as (Sr/Ta₂) in a raw material was set to 0.1 mol/L and its supply flow quantity was set to 0.02 mL/min.

On the other hand, a raw material concentration of a Bi organic metal complex was set to 0.2 mol/L, and its supply flow quantity was set to 0.02 mL/min.

As a solvent, n-Hexane was used to manufacture a raw material solution. Its supply quantity was set to 0.2 mL/min with respect to each raw material flow quantity.

On the other hand, as a carrier gas, a material obtained by mixing oxygen in an Ar gas was used.

The carrier gas was heated to 200° C. before being introduced into a passage. It is to be noted that its flow quantity was set to 210 mL/min.

It is to be noted that a supply passage of the raw material solution and a gas passage were cooled.

Under such conditions, the SBT film was formed, and scattering of fine particles in the film was observed.

### COMPARATIVE EXAMPLE 1

In this example, an SBT film was formed like Embodiment 1 except heating of a carrier gas, and scattering of fine particles in the film was observed.

In case of Embodiment 1, a quantity of fine particles was reduced to 1/50 or below as compared with that of Comparative Example 1.

### Embodiment 2

In this example, a film was formed while changing a heating temperature of a carrier gas to 50° C., 100° C., 150° C., 200° C., 250° C. and 300° C.

In case of 50° C., the number of fine particles was smaller than that in Comparative Example 1. The number of fine particles was rapidly reduced from 100° C., and it became the smallest number at 200° C. At 300° C., the number of fine particles was 1/30 or below as compared with the comparative example.

### INDUSTRIAL APPLICABILITY

Using the vaporizer according to the present invention can avoid generation of fine particles having a particle diameter of 1 μm or below which is concerned when a conventional vaporizer is used.

1. A vaporization method, wherein a raw material solution is brought into contact with a heated carrier gas and carried to a subsequent step.

2. The vaporization method according to claim 1, wherein a temperature of the heated carrier gas is 100 to 300° C.

3. The vaporization method according to claim 2, wherein a temperature of the heated carrier gas is 200 to 250° C.

4. The vaporization method according to claim 1, wherein the raw material solution is obtained by solving an organic metal compound in a solvent.

5. The vaporization method according to claim 1, wherein the carrier gas is an inert gas.

6. The vaporization method according to claim 1, wherein the carrier gas is a gas which contains an oxidizing gas in an inert gas.

7. The vaporization method according to claim 1, wherein a speed of the carrier gas is set to a subsonic speed to a sonic speed to introduce the raw material solution.

8. The vaporization method according to claim 1, wherein the raw material solution is introduced into a passage of the carrier gas through a hole having a diameter of 0.05 mm to 0.5 mm.

9. The vaporization method according to claim 1, wherein the solvent of the raw material solution is contained in the carrier gas before introducing the raw material solution.

10. The vaporization method according to claim 1, wherein a raw material concentration in the raw material solution is 0.2 mol/L or below.

11. A vaporizer having: a vaporization chamber; a carrier gas passage communicating with the vaporization chamber; a raw material solution lead-in port through which the raw material solution is led into the passage; and means for heating the carrier gas.
